(19) United States
(12) Patent Application Publication
(10) Pub. No.: US 2010/0178612 A1
(43) Pub. Date: Jul. 15, 2010

(54) LITHOGRAPHIC APPARATUS AND DEVICE MANUFACTURING METHOD

(75) Inventors: Johannes ONVLEE, 's-Hertogenbosch (NL); Jan Jaap Kuit, Veldhoven (NL); Joost Kos, Eindhoven (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/642,610

(22) Filed: Dec. 18, 2009

Related U.S. Application Data
(60) Provisional application No. 61/140,692, filed on Dec. 24, 2008.

(51) Int. Cl. G03F 7/20; G03B 27/54

(52) U.S. Cl. 430/311; 430/322; 355/70

(57) ABSTRACT

A lithographic apparatus includes a support constructed to support a patterning device for imparting a radiation beam with a pattern in its cross-section to form a patterned radiation beam and a substrate table constructed to hold a substrate. A projection system projects the patterned radiation beam onto a target portion of the substrate. The patterning device includes one or more alignment patterns, the lithographic apparatus including a secondary illumination system effective to illuminate each alignment pattern with radiation separate from said radiation beam, the projection system projecting an image of each alignment pattern onto the substrate table. The substrate table includes a number of sensor arrangements, each sensitive to the projected image of one of said alignment patterns.

This application claims priority and benefit under 35 U.S.C. §119(e) to U.S. Provisional Patent Application No. 61/140,692, entitled “Lithographic Apparatus and Device Manufacturing Method,” filed on Dec. 24, 2008. The content of that application is incorporated herein in its entirety by reference.

### FIELD

The present invention relates to a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to acquire a desired pattern on a target portion on a substrate, it is necessary for the mask to be aligned with respect to the substrate. It is known that this can be achieved by:
1. aligning the substrate with respect to the substrate stage carrying the substrate; and
2. then aligning the mask to the substrate stage.

As a result of these two actions the mask is then aligned with respect to the substrate. Where a single stage lithography apparatus is used, these two actions may be carried out just before exposure of the substrate. However where a dual stage lithography apparatus is used, the first action may be carried out at a position remote from the exposure position, then the substrate stage with the substrate positioned on it being transferred to the exposure position and the second action being performed.

A known way for the relative positions of a number of markers on a wafer to be measured, is relative to a fiducial, which is fixed to the wafer table outside the area of the wafer. The fiducial is in the form of a plate having an opaque coating into which is etched a pattern corresponding to the alignment marker. Underneath the plate there is an electronic sensor. The location of the fiducial can then be measured using the same alignment sensor, which is used to locate the alignment markers on a wafer thus measuring the relative positions of the alignment markers on the wafer and the fiducial.

In the second stage the mask is aligned with respect to the substrate stage, it is known to use an image sensor known as a transmission image sensor (TIS). U.S. Pat. No. 7,333,175, the contents of which are incorporated herewith by reference, describes a method and a system for aligning a mask with a target area of a substrate using a TIS measurement technique. A TIS measurement is performed by imaging a first alignment pattern provided on the mask through the projection system for the lithography apparatus onto a second alignment pattern provided on the substrate stage. Inside the substrate stage, behind the second alignment pattern, a light sensitive sensor is provided that measures the light intensity of the image of the first alignment pattern. Thus when the projected image of the first alignment pattern exactly matches the second alignment pattern, the sensor will measure a maximum intensity. By use of differently oriented alignment patterns, the TIS patterns may be scanned through three dimensions, so as to locate the plane of best focus and also the XY position of the mask.

When using a stepper rather than a scanner, the entire substrate is illuminated at a single time. There is then a problem with such an arrangement, in that the alignment markers on the mask are usually positioned outside the active image area, which produces the required structure on the wafer. This means that the illumination source has to provide a large area beam in order to illuminate the alignment markers. The large area beam should have an evenly distributed total available energy over the large area. Thus the total intensity is lower, implying longer exposure times and thus lower throughput than for a less large area beam produced by the illumination source.

It is an object of the present invention to provide a lithographic apparatus wherein this problem may be at least alleviated.

JP 2007-299909 discloses a positioning device for aligning a mask with a substrate in which two or more LEDs of different wavelengths are used to project a pattern on a mask onto a wafer.

### SUMMARY

According to a first aspect of the invention, there is provided a lithographic apparatus comprising:

a support constructed to support a patterning device, the patterning device including a pattern which may be imparted to a cross-section of a radiation beam to form a patterned radiation beam;

a substrate table constructed to hold a substrate; and

a projection system configured to project the patterned radiation beam onto a target portion of the substrate,

wherein the patterning device includes one or more alignment patterns to be imparted to the radiation beam;

said lithographic apparatus includes a secondary illumination system effective to illuminate each of said alignment patterns with radiation separate from said radiation beam;

said projection system is configured to project each said alignment pattern to produce an image of each said alignment pattern at a position measurable relative to said substrate; and

the lithographic apparatus includes one or more sensor arrangements effective to detect the projected image of one of said alignment patterns.

According to a second aspect of the invention there is provided a lithographic method comprising the steps of:

supporting a patterning device, the patterning device including a pattern which is imparted to cross-section of a radiation beam to form a patterned radiation beam;

supporting a substrate on a substrate table; and

projecting the patterned radiation beam onto a target portion of the substrate,

wherein the patterning device includes one or more alignment patterns to be imparted to the radiation beam;

illuminating each of said alignment patterns with radiation separate from said radiation beam;

projecting each said alignment pattern to produce an image of each said alignment pattern at a position measurable relative to said substrate; and

detecting each said projected image of each said alignment patterns.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a schematic diagram of a transmission image sensor in use in a lithographic apparatus;

FIG. 3 is a plan view of a mask which may be used in a lithographic apparatus in accordance with an embodiment of the invention;

FIG. 4 is a side view of the mask of FIG. 3, used in a lithographic apparatus in accordance with an embodiment of the invention; and

FIG. 5 is a further side view of the mask of FIG. 3, used in a lithographic apparatus in accordance with an embodiment of the invention.

### DETAILED DESCRIPTION

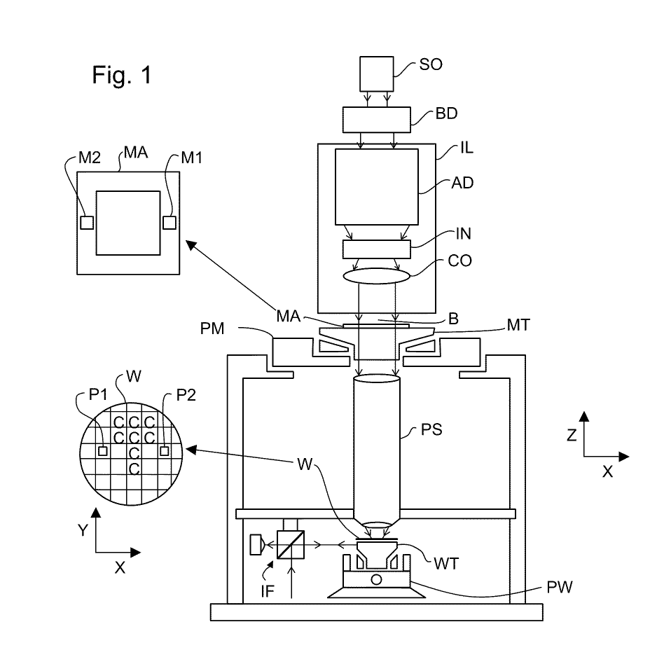

FIG. 1 schematically depicts a lithographic apparatus according to one embodiment of the invention. The apparatus comprises:
an illumination system (illuminator) IL configured to condition a radiation beam B (e.g. UV radiation).
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WT constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called LCD assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment markers M1, M2 and substrate alignment markers P1, P2. Although the substrate alignment markers as illustrated occupy dedicated target portions, they may be located in spaces between target portions (these are known as scribe-lane alignment markers). Similarly, in situations in which more than one die is provided on the mask MA, the mask alignment markers may be located between the dies.

In the particular embodiment of the invention to be described, the depicted apparatus is used in a step mode, the mask table MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

It will be appreciated that while the scanners are used for imaging with the highest accuracy, a stepper can be advantageous for imaging semiconductors layers with lower requirement as the whole pattern may be exposed in a single image, achieving a higher throughput. As in a stepper the mask stage is fixed in position, it is not possible to reposition the mask so that the alignment markers outside the active image area are within the area illuminated by the radiation beam B. If the radiation beam is used to illuminate the alignment markers, the area of illumination should be expanded giving a corresponding reduction in image intensity leading to an increase in exposure time and thus reducing throughput.

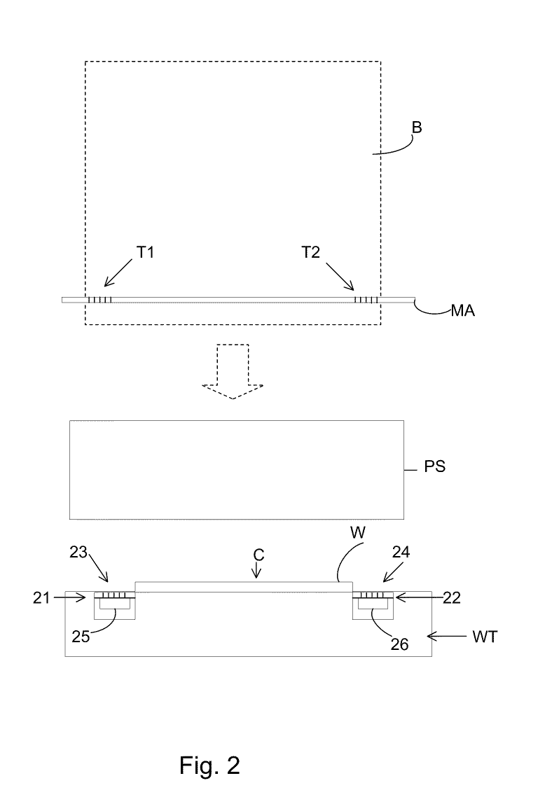

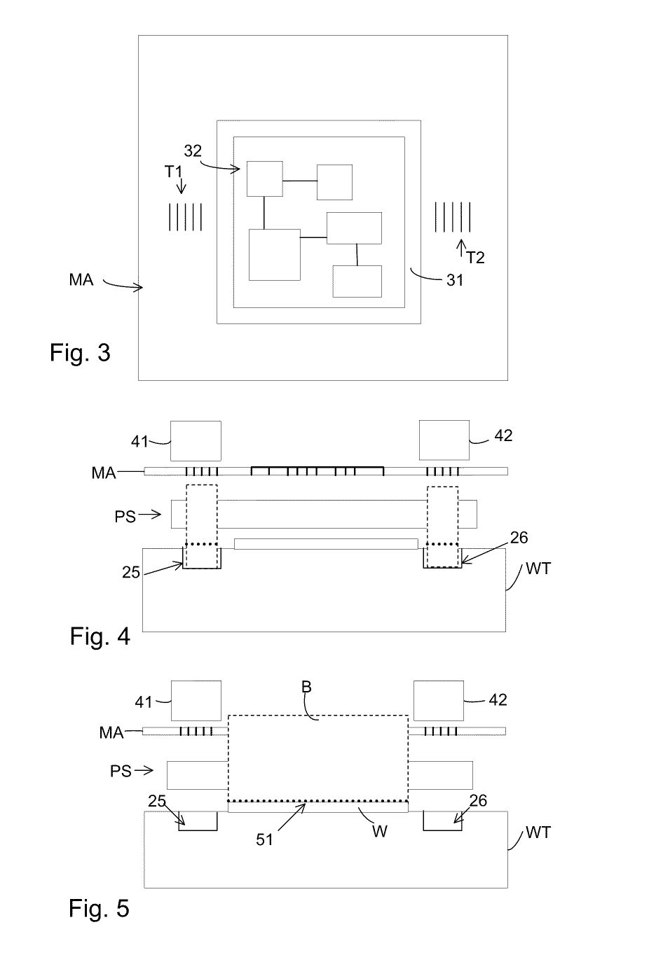

Referring to FIGS. 2 and 3, these figures illustrate the principle of operation of the TIS. In particular, FIG. 3 illustrates a mask MA provided with a number of TIS alignment markers. The mask illustrated in FIGS. 2 and 3 only includes two alignment markers, T1, T2. It will be appreciated, however, that other marker configurations are possible using a different number of markers, for example four markers, with two pairs of markers on two opposing edges of the mask MA. The center of the mask MA includes a pattern 32 (shown very schematically) for projection onto the target portion C of the wafer W on the wafer table WT, the centre of the mask MA being, in this particular example, surrounded by a chromium border 31, which serves to isolate the pattern 32 for projection. It will be appreciated that the positions of the alignment markers will depend on the actual application, including, for example, steppers, scanners and masks for use with lithographic apparatus of different manufacturers. In particular, the alignment markers may lie towards the centre of the pattern 32. Furthermore the chromium border may be omitted.

Whilst the alignment markers T1, T2 have been shown as line patterns, in one particular example each TIS marker is divided into three parts:
1. a square ratio marker for coarse measurements, the centre of the ratio marker containing a small cross which can be used as a reference for optical quality inspection of a metrology tool;
2. an X alignment marker containing vertical gratings; and
3. a Y alignment marker containing horizontal gratings.

It will be appreciated however, that other configurations are possible, dependent on the application.

The mask is illuminated using the radiation beam B which is projected through the projection system PS, to project images of the alignment markers on respective fiducials, each fiducial comprising a plate 21, 22 having an opaque coating onto which is etched a pattern 23, 24 corresponding to the alignment markers T1, T2. Underneath each plate 21, 22 there is provided an electronic sensor 25, 26, for example a CCD. The output of each sensor 25, 26 will give an indication of the alignment of the image of each alignment marker T1, T2 on the mask MA with the patterns 23, 24 formed on the wafer table WT.

In known arrangements, as indicated in FIG. 2, during the alignment procedure the projection lens system PS is configured to project the same beam to illuminate both the pattern 32 for imaging on the substrate and each of the alignment markers. A beam interceptor blade (not shown) as disclosed in EP 1 431 829, the contents of which are incorporated herein by reference, may be used to prevent exposure of the alignment markers on the wafer W during exposure of the image and can be used to limit the exposure of one or more of the alignment markers during the alignment procedure. However as discussed above, such an arrangement leads to the result that the cross section of the beam B should be wide enough to cover both the pattern 32 on the wafer W and the alignment markers T1, T2.

According to an embodiment of the present invention separate light sources, other than the illumination system that produces the beam B, are used to illuminate the alignment markers. By such an arrangement the problems inherent with the prior art arrangements may be avoided.

In accordance with the embodiment of the invention and as shown in FIGS. 4 and 5, in respect of each alignment marker on a mask, as shown for example in FIG. 3, there is provided a respective LED 41, 42 at a location corresponding to the location of each alignment mark T1, T2. Each LED has a wavelength that is the same wavelength as that of the radiation beam B, for example 365 nm. If required, narrowband optical filters (not shown) may be placed in the beam path in front of the LEDs 41, 42, to reduce the bandwidth.

Turning now to FIG. 4, in a method in accordance with an embodiment of the invention, during the alignment procedure each LED is arranged to illuminate a respective alignment marker T1, T2 by the radiation indicated in a dashed line block, the radiation passing through the projection lens system PS as in FIG. 2 to be intercepted by the TIS sensors 25, 26. After the alignment procedure has been performed, the LEDs are switched off and the illumination beam B is used to illuminate the central image portion of the mask as indicated by the dashed line block in FIG. 5, the cross section area of the beam B being such as not to pass through the alignment markers T1, T2. An image 51 of the pattern 32 on the mask MA is thus produced on the wafer W.

The LEDs may be located in a number of locations. As indicated in FIGS. 4 and 5 the LEDs may be located just above the mask MA just outside the periphery of the radiation beam B. Alternatively the LEDs may be located at a point further upstream the illumination system IL. It will be appreciated that where the sources are remote from the mask, the illuminating radiation for the alignment markers can be brought to a point just above the mask MA by, for example, an optical fibre (not shown). Alternatively the extra light sources may be positioned remotely, with a suitable optical system, including for example a folding mirror (not shown) and possibly a further lens (not shown), just above the mask MA.

In order to minimize disturbance of the lithography processing, the LEDs 41,42 will normally be switched on during the alignment process and off during the lithographic process. As a consequence of the invention, the numerical aperture (NA) of the illuminator IL can be chosen to be smaller than the maximum NA of the projection lens system PS. In this way the alignment markers will not pose additional size constraints on the projection lens system PS.

It will be appreciated that other light sources than LEDs may be used, although LEDs are particularly convenient. For example, for so-called “broadband steppers” which use an H9 lamp covering the G, H and I-line spectrum, a solid-state laser with a wavelength within this spectrum can be used in an alignment method in accordance with an embodiment of the invention. It will be appreciated that the wavelengths of the LEDs extra light sources will generally overlap that of the radiation source, as the projection system is only optimized for projection of radiation of a single wavelength or wavelength band. A shutter arrangement such as a beam interceptor blade could be used as in the prior art arrangements as described above, but generally it will simpler to simply turn the extra light sources on and off as is possible with an LED. It will also be appreciated that whilst in the particular example described before, a wavelength of 365 nm is used, any appropriate wavelength may be used.

It will be appreciated that in the illumination of the alignment markers, the values of the outer and/or inner radial extent (σ-outer and σ-inner) of the intensity distribution of the beam do not have to be the same as the values for illumination of the pattern projected on the wafer W. Other illumination modes are possible. It will also be appreciated that differences in NA and σ-outer and σ-inner may in principle affect the accuracy of measurement, but this is generally not significant in a stepper.

It will also be appreciated that in a system in accordance with the invention LEDs may be switched off and on faster than the interceptor blades described above can be moved, in order to select the pattern for imaging on the mask MA or the alignment markers.

It will also be appreciated that whilst the above apparatus incorporates a TIS alignment system, other alignment systems incorporating alignment patterns produced by a radiation source are possible in an apparatus and method in accordance with the invention. For example, where the alignment markers lie towards the center of the pattern to be imaged on the wafer, the sensors arranged to detect the projected images of the alignment markers may be positioned other than on the substrate table as long as it is possible to measure the distance between the images of the alignment patterns and the substrate.

It will also be appreciated that whilst the invention finds particular application in a stepper, the invention is also applicable to a scanner, the positions of the markers, the separate illumination sources and the corresponding detectors being arranged in the mode to affect an effective expansion of the beam in two orthogonal directions.

It will also be appreciated that use of the LEDs is cheaper than using an illumination system having a large NA in order to illuminate both the target and the alignment markers. There will be no intensity loss caused by the use of an illumination system having a larger NA and thus no associated throughput loss.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A lithographic apparatus comprising:
a support constructed to support a patterning device, the patterning device including a pattern which may be imparted to a cross-section of a radiation beam to form a patterned radiation beam;
a substrate table constructed to hold a substrate; and
a projection system configured to project the patterned radiation beam onto a target portion of the substrate,
wherein the patterning device includes one or more alignment patterns;
said lithographic apparatus includes a secondary illumination system effective to illuminate each of said alignment patterns with radiation separate from said radiation beam;
said projection system is configured to project each said alignment pattern to produce an image of each said alignment pattern at a position measurable relative to said substrate; and
the lithographic apparatus includes one or more sensors constructed and arranged to detect the projected image of one of said alignment patterns.

2. A lithographic apparatus according to claim 1 wherein said secondary illumination system comprises a respective LED for each alignment pattern.

3. A lithographic apparatus according to claim 1 wherein said secondary illumination system comprises a respective solid-state laser for each alignment pattern.

4. A lithographic apparatus according to claim 1 wherein said radiation beam and said radiation separate from the radiation beam are of a same wavelength.

5. A lithographic apparatus according to claim 1 wherein said one or more alignment patterns are positioned on the patterning device outside a boundary of said pattern to be imparted to the radiation beam.

6. A lithographic apparatus according to claim 5 wherein said images of said alignment patterns are produced on said substrate table.

7. A lithographic apparatus according to claim 1 wherein each said sensor comprises a transmission image sensor.

8. A lithographic method comprising:
supporting a patterning device, the patterning device including a pattern which is imparted to a cross-section of a radiation beam to form a patterned radiation beam and one or more alignment patterns;
supporting a substrate on a substrate table;
projecting the patterned radiation beam onto a target portion of the substrate;
illuminating each of said alignment patterns with radiation separate from said radiation beam;
projecting each said alignment mark to produce an image of each said alignment pattern at a position measurable relative to said substrate; and
detecting each said projected image of each said alignment patterns.

9. A method according to claim 8 wherein said distinct radiation is provided by a respective LED for each alignment pattern.

10. A method according to claim 8 wherein said distinct radiation is provided by a respective solid state laser for each alignment pattern.

11. A method according to claim 8 wherein said radiation beam and said radiation separate from the radiation beam are of a same wavelength.

12. A method according to claim 8 wherein said one or more alignment patterns are positioned on the patterning device outside a boundary of said pattern to be imparted to the radiation beam.

13. A method according to claim 12 wherein said images of said alignment patterns are produced on said substrate table.

14. A method according to claim 8 wherein the detecting is performed using a transmission image sensor.

15. A device manufacturing method comprising:
supporting a patterning device, the patterning device including a pattern which is imparted to a cross-section of a radiation beam to form a patterned radiation beam and one or more alignment patterns;
supporting a substrate on a substrate table;
projecting the patterned radiation beam onto a target portion of the substrate;
illuminating each of said alignment patterns with radiation separate from said radiation beam;
projecting each said alignment mark to produce an image of each said alignment pattern at a position measurable relative to said substrate;
detecting each said projected image of each said alignment patterns; and
forming a microelectronic device on said substrate.
